(19) United States
(12) Patent Application Publication
(10) Pub. No.: US 2026/0247742 A1
(43) Pub. Date: Aug. 20, 2026

(54) BACKSIDE-CONTACT SOLAR CELL AND METHOD FOR PRODUCING A BACKSIDE-CONTACT SOLAR CELL

(71) Applicants: Erik HOFFMANN, Stuttgart (DE); Massimo CENTAZZO, Karlsruhe (DE)

(72) Inventors: Erik HOFFMANN, Stuttgart (DE); Massimo CENTAZZO, Karlsruhe (DE)

(73) Assignee: Silfab Solar Cells SC Inc., Fort Mill, SC (US)

(21) Appl. No.: 19/540,543

(22) Filed: Feb. 13, 2026

(30) Foreign Application Priority Data
Feb. 20, 2025 (DE) 10 2025 106 4598

(51) Int. Cl. H10F 77/20; H10F 71/00; H10F 77/30

(52) U.S. Cl. CPC H10F 77/211; H10F 71/121; H10F 77/219; H10F 77/315

(57) ABSTRACT

A back-contact solar cell and a method for manufacturing a back-contact solar cell are disclosed. The method includes forming a first tunneling layer on a back side of a semiconductor substrate, forming a first conductive layer on the first tunneling layer, forming an etch-resistant barrier layer on the first conductive layer with interruptions, openings or gaps in etching areas, etching in the etching areas to produce a plurality of pedestal-like elevations and to undercut the etch-resistant barrier layer, forming a second tunneling layer in the etching areas, between the plurality of pedestal-like elevations, forming a second conductive layer in the etching areas, between the plurality of pedestal-like elevations, and on the etch-resistant barrier layer by directed deposition, and completely removing the etch-resistant barrier layer and the second conductive layer on the etch-resistant barrier layer. The first and second conductive layers have different doping types.

### CROSS-REFERENCE TO RELATED APPLICATIONS

This application claims priority to German Pat. Appl. No. 10 2025 106 459.8, filed on Feb. 20, 2025, the contents of which are incorporated by reference herein in its entirety.

### FIELD OF THE INVENTION

The invention relates to a back-contact solar cell with features as described herein and a method for producing a back-contact solar cell with such features.

### DISCUSSION OF THE BACKGROUND

In a back-contact solar cell, electrodes of opposite polarities, as well as emitter regions and base regions, are arranged on the back side of the solar cell. The back side of the solar cell is the side facing away from the sun during the operation of the solar cell. Accordingly, the front side of the solar cell is the side facing the sun.

Back-contact solar cells can generally achieve a higher efficiency than solar cells in which electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, as well as the emitter and base regions, are arranged alternately on the back side, with a small gap between the different regions.

Back-contact solar cells can generally achieve a higher efficiency than solar cells where electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, and thus also the emitter and base regions, are alternately arranged on the back with a small spacing between adjacent emitter and base regions.

Generating a large number of p-n junctions with small spacing is technically significantly more challenging than, for example, a conventional solar cell with a large-area, bilateral contact p-n junction. The alternately arranged emitter and base regions on the back side can be realized, for instance, using laser irradiation. In this process, n-type and p-type dopants are locally introduced into a semiconductor substrate by temporally and spatially separated melting of the surface with laser irradiation, thereby creating either a p-type or n-type doped region depending on the dopant. Such a laser doping method is disclosed, for example, in DE 10 2013 219 564 A1. The described structuring of the back side allows for efficiencies of up to 24% due to low internal series resistances and high current yields.

Even higher efficiencies are essentially limited by recombination mechanisms in the base as well as on the heavily-doped contact and non-contact surfaces. Recombination in the base depends on the quality of the semiconductor substrate, and can only be influenced to a limited extent in the manufacturing process of the solar cell. Recombination mechanisms at the doped n-type and p-type surfaces are limited in the non-contact areas by Auger recombination only when there is good surface passivation, with Auger recombination increasing with the dopant concentration in silicon. In contact areas, where metal electrodes contact silicon, the contact with the metal leads to high interface recombination. During the manufacturing process, Auger recombination at the non-contact surfaces can be reduced by minimizing doping. A high dopant concentration is advantageous at the contact surfaces, as this reduces contact resistance and interface recombination.

To address this discrepancy, the use of so-called passivating or charge carrier-selective contacts is known, as seen in, for example, DE 10 2013 219 564 A1 or WO 2014/100004 A1. The electrodes do not directly contact the crystalline silicon wafer, which serves as an absorber, but are separated by a thin dielectric layer, such as a silicon oxide layer or by an undoped hydrogenated amorphous silicon layer (a-Si:H). The passivation layer passivates the silicon surface on the one hand. On the other hand, the passivation layer is so thin that charge carriers (particularly electrons) can tunnel through the passivation layer from the semiconductor to the electrode, or from the electrode to the semiconductor (depending on the polarity). Therefore, the passivation layer can be referred to as a tunneling layer through which charge carriers can tunnel. The tunneling layer may also have small holes, e.g., in the nanometer (nm) range, that can allow for current flow.

In order to excite only one type of charge carrier to tunnel through the tunneling layer depending on the polarity of the electrode, band bending is required. For example, band bending in silicon can be generated by a highly doped conductive layer, such as an n-type or p-type doped silicon layer, on the passivation layer. Doping this highly doped conductive layer above the passivation layer leads to band bending in the silicon substrate below the passivation layer. Therefore, classical doping of the silicon base to create a p-n junction is no longer necessary. Since the silicon substrate is no longer doped or only slightly doped, Auger recombination in the substrate decreases. The spatial separation of a metal/silicon interface of the electrodes from the silicon substrate also reduces interface recombination. Nevertheless, a low contact resistance can be achieved because the electrodes contact the heavily doped silicon layer. Doped silicon layers, for example, include amorphous, partially crystalline, or polycrystalline silicon layers or silicon carbide layers with a thickness of 20 nm to 400 nm, which can be deposited using methods such as PECVD, LPCVD, APCVD, or PVD.

Back-contact solar cells with charge carrier-selective contacts of opposite polarities have so far achieved an efficiency of up to 27.3%. However, the production of such solar cells is very complicated, as the two differently-doped passivating contacts have been made only using various complex masking and fabrication steps. High precision and fine resolution of the masking and fabrication have been necessary. The distance between the charge carrier-selective contacts of opposite polarities should not exceed the diffusion length of the free charge carriers. However, large distances can also lead to an increase in internal series resistance due to lateral current flow in the base.

The differently-doped silicon layers of the charge carrier-selective contacts can also be separated either by an undoped silicon layer or by a spatial separation (e.g., a trench or a break). Without such separation, the transition between the differently-doped layers has a defect-rich p-n junction, which limits the efficiency of the solar cell. Ideally, the separation should be as fine as possible, as a large area for separation can adversely affect the short-circuit current and the open-circuit voltage.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is therefore an object of the present invention to provide a rear contact solar cell and a method for manufacturing a rear contact solar cell, whereby the solar cell has a high efficiency and can be produced cost-effectively and efficiently.

This object is provided by a method for manufacturing a back-contact solar cell with features as described herein. The method comprises:

Providing a semiconductor substrate with a front side and a back side. The semiconductor substrate may include or consist essentially of silicon (e.g., silicon doped with a conventional n-type or p-type dopant in an amount sufficient to control variations in electrical properties of the silicon due to inherent defects and contaminants).

Forming a first tunneling layer, in particular on the back side of the semiconductor substrate. It is also conceivable that the first tunneling layer can also be formed on the front side of the semiconductor substrate.

Forming a first conductive layer with an initial doping on the first tunneling layer.

Forming an etch-resistant barrier layer on the first conductive layer. The etch-resistant barrier layer can include or consist essentially of a dielectric and/or a polymer.

The etch-resistant barrier layer may have interruptions, openings or gaps in a plurality of etch areas. The etch-resistant barrier layer can, for example, be formed or applied by printing or deposition through a mask. Alternatively, if formed without interruptions, openings or gaps, the etch-resistant barrier layer can be removed (e.g., by etching or laser ablation) in the plurality of etch areas. In the etch areas, in particular, no etch-resistant barrier layer is present.

Etching the etch areas to create pedestal-like elevations (e.g., by the etching). The pedestal-like elevations can be formed from the semiconductor substrate, the first tunneling layer, and/or the first conductive layer. In particular, etching can remove or etch the first conductive layer, the first tunneling layer, and optionally a surface or surface portion of the semiconductor substrate in the etched areas and in adjacent areas under the etch-resistant barrier layer. The etch-resistant barrier layer can thus be undercut in the etching process. The etching can comprise, for example, wet chemical etching or dry etching. It is also conceivable that only the first conductive layer can be removed or etched through the etching. In that case, the pedestal-like elevations may be formed solely from the first conductive layer.

Forming a second tunneling layer, particularly in the areas between the pedestal-like elevations of the semiconductor substrate (e.g., when the first tunneling layer is etched in the etch areas).

Forming a second conductive layer with a second doping that is opposite to the first doping, particularly in the areas between the pedestal-like elevations.

Completely removing the etch-resistant barrier layer and the second conductive layer on the etch-resistant barrier layer. In this process, the above steps may be carried out in the stated order.

This allows a back-contact solar cell to be produced easily and cost-effectively. In particular, it enables separation between the first conductive layer and the second conductive layer, and thus, electrical contacts to the solar cell on the back of the semiconductor substrate can be implemented as efficiently as possible.

In particular, this allows a plurality of first areas each with a first conductive layer, a plurality of second areas each with a second conductive layer, and a plurality of third areas to be created on the rear side, wherein the third areas are free of the first conductive layer and/or the second conductive layer.

The first and/or second tunneling layer can be or comprise a passivation layer. The respective passivation layer can, for example, include a dielectric layer such as a silicon oxide (SiOx), silicon nitride (SiNx), a silicon oxynitride (SiON), or an intrinsic amorphous silicon layer.

The etch-resistant barrier layer can be resistant to etching with a silicon etchant. The etch-resistant barrier layer can be or comprise an etch mask. The etch-resistant barrier layer can, in particular, be removed or dissolved using a mask etchant or a mask solution that does not etch or dissolve the first conductive layer and/or the second conductive layer. In particular, the first and/or the second conductive layer can be resistant to the mask etchant or the mask solution.

According to a refinement of the method, removing the etch-resistant barrier layer and/or the second conductive layer on the etch-resistant barrier layer can comprise a lift-off process. In particular, by covering the etch-resistant barrier layer with the second conductive layer, which is especially resistant to mask etchants or mask solution, the etch-resistant barrier layer can be etched laterally, and the second conductive layer can be subsequently removed using the lift-off process.

This allows the etch-resistant barrier layer and/or the second conductive layer on the etch-resistant barrier layer to be removed simply and completely.

According to a further development of the method, the second conductive layer arranged on the etch-resistant barrier layer can be detached and/or removed during or after the removal of the etch-resistant barrier layer. The second conductive layer arranged on the etch-resistant barrier layer can be detached or removed together (in a single process step) with the etch-resistant barrier layer.

This allows the second conductive layer arranged on the etch-resistant barrier layer to be removed using simple means, in particular in a single process step together with the removal of the etch-resistant barrier layer.

According to a refinement of the method, the first conductive layer may be or comprise a doped silicon layer. Alternatively or additionally, the second conductive layer may be or comprise a doped silicon layer.

This allows the first and/or second conductive layer to be implemented simply.

According to a refinement of the method, the first conductive layer and/or the second conductive layer can be doped or deposited to be conductive in situ. Alternatively, the first conductive layer and/or the second conductive layer as deposited can initially be intrinsic, and subsequently doped ex situ, in particular by furnace diffusion, ion implantation, or laser diffusion.

This allows the first and/or second conductive layer to be implemented simply and flexibly.

According to an embodiment of the method, the second conductive layer can be at least partially porous, particularly in the area of the etch-resistant barrier layer. Alternatively or additionally, the second conductive layer can have holes at least in certain areas, especially in the area(s) of the etch-resistant barrier layer.

This can accelerate the removal of the etch-resistant barrier layer (and thus the second conductive layer on the etch-resistant barrier layer) simply.

According to an embodiment of the method, the etch-resistant barrier layer can have irregularities. Alternatively or additionally, the etch-resistant barrier layer can be rough (e.g., have a predetermined minimum roughness).

This allows the removal of the etch-resistant barrier layer (and thus the second conductive layer) to be accelerated simply. In particular, this makes it possible to create holes in the second conductive layer on the etch-resistant barrier layer using simple methods.

According to an embodiment of the method, the second conductive layer may partially cover the etch-resistant barrier layer. In other words, the etch-resistant barrier layer may have areas that are not covered by the second conductive layer. The second conductive layer, in particular, may not fully cover the etch-resistant barrier layer, but may have interruptions, gaps and/or openings therein.

This allows for removal of the etch-resistant barrier layer (and thus the second conductive layer) to be accelerated simply.

According to a further embodiment of the method, after removing the etch-resistant barrier layer, activation of dopants and/or crystallization of the first conductive layer and/or the second conductive layer can be carried out. This can, for example, comprise heating at a high temperature.

This can further optimize the method.

According to a further embodiment of the method, after removing the etch-resistant barrier layer, the resulting structure can be cleaned. In particular, a native oxide (e.g., on the first conductive layer and/or the second conductive layer) can be removed. Cleaning the structure resulting from removing the etch-resistant barrier layer can be conducted before and/or after activation of dopants and/or crystallization of the first and/or second conductive layer(s).

This can further optimize the method.

According to an advancement of the method, after removing the etch-resistant barrier layer, at least one passivation layer, and in particular, a passivation layer stack, can be formed on the back side and, optionally, the front side of the substrate or solar cell.

This allows the passivation of the solar cell to be implemented simply, thereby further optimizing the method.

According to an advancement of the method, the method may include the steps of forming first electrodes, and alternatively or additionally, forming second electrodes.

This allows contacts to the substrate or to the solar cell to be implemented simply.

The process can comprise at least one, and optionally more than one, of the following steps:

Forming a third conductive layer in the third areas and/or a fourth conductive layer on the front side of the semiconductor substrate or the solar cell using a furnace (e.g., by diffusion of a dopant in the third areas and/or the front side of the semiconductor substrate).

Removing a silicate glass layer formed during the furnace diffusion, for example, a phosphosilicate glass or a borosilicate glass, particularly by (wet chemical) etching.

In particular, in the first area, a first electrode contacts the second conductive layer through first interruptions, gaps or openings in the passivation layer, and in the second area, a second electrode contacts the second conductive layer through second interruptions, gaps or openings in the passivation layer.

Etching a silicon layer deposited in the third areas, provided that the silicon layer in the third areas is thinner than the layer in the second areas. The etching duration can be adjusted so that the silicon layer in the third areas can be completely removed or at least significantly reduced in thickness. In the second areas, the silicon layer should be reduced only slightly in relation to its thickness, in particular so as not to impair the performance of the solar cell.

The above objective(s) may be provided by a back-contact solar cell with at least some of the features described herein.

The backside-contact solar cell comprises a semiconductor substrate with a front side and a back side. The semiconductor substrate may include silicon or consist essentially of silicon. The back side of the semiconductor substrate comprises a plurality of first regions, a plurality of second regions, and a plurality of third regions. The first regions each comprise a first conductive layer. The second regions each comprise a second conductive layer. The third regions are free of the first conductive layer and/or the second conductive layer. In other words, no first and/or second conductive layer is in the third regions. The first conductive layer and the second conductive layer can have different dopants or different dopant types, and can thus be configured as n-type or p-type. The third regions can be self-aligned, without additional masking or structuring steps.

The first conductive layers and/or the second conductive layers can each comprise or consist essentially of amorphous, semi-crystalline, or polycrystalline silicon (or similar materials, for example, silicon carbide). The conductive layers can further comprise a transparent conductive metal oxide (TCO). The third regions in particular provide electrical insulation or at least a high resistance between the first and second regions.

A first tunneling layer is between the first conductive layer and the semiconductor substrate, which in particular passivates the surface of the semiconductor substrate. A second tunneling layer is between the second conductive layer and the semiconductor substrate. The first regions and the second regions may further comprise passivating contacts.

The solar cell comprises a plurality of first electrodes and a plurality of second electrodes. In the first regions, each first electrode electrically contacts a first conductive layer. In the second regions, each second electrode electrically contacts a second conductive layer. The first regions comprise pedestal-like elevations on the semiconductor substrate.

The solar cell is manufactured using a method according to the above description.

With regard to the advantages achievable with the solar cell, reference is made to the related descriptions of the method. For further configurations of the solar cell, the measures described in connection with the method and/or the measures explained below may be used.

A surface on the back side of the semiconductor substrate or solar cell, or surfaces on both the back side and the front side of the semiconductor substrate or solar cell can be at least partially, in particular completely, covered with a dielectric (passivating) layer. The dielectric layer can comprise a layer stack, that is, two or more layers (e.g., of different dielectric materials).

The dielectric passivation layer can have a first interruption, gap or opening in each of the first regions, and a second interruption, gap or opening in each of the second regions. Accordingly, the dielectric layer can have a plurality of first interruptions, openings or gaps and a plurality of second interruptions, openings or gaps, particularly on the back side of the semiconductor substrate or the solar cell. The first electrodes can electrically contact the first conductive layers, in particular, through the first interruptions, gaps or openings. The second electrodes can electrically contact the second conductive layers, in particular, through the second interruptions, gaps or openings.

When the conductive layers include a transparent conductive metal oxide, the back side of the solar cell can omit an additional passivation layer, and the electrodes can contact the respective conductive layers directly.

The pedestal-like elevations of the semiconductor substrate can each have a cross-section that is rounded in a first direction, or that widens (i.e., gets larger), tapers (i.e., gets smaller), or maintains a constant width (i.e., has substantially vertical sidewalls). In particular, the shape of the cross-section of the pedestal-like elevations can be trapezoidal or rectangular.

The first direction may refer to a direction pointing away from the back side of the solar cell. It is also conceivable that the first direction can be a direction pointing towards the back side of the solar cell. The first direction is, more particularly, perpendicular to the front and back sides of the solar cell.

In particular, due to the cross-sections of the pedestal-like elevations widening in a direction away from the semiconductor substrate or the solar cell, and/or due to the etch-resistant barrier layer, the third regions can be formed in a recessed area that widens transversely to the first direction, and thus in the “shadow” (with respect to the first direction) of the first regions. The first conductive layers and the second conductive layers are therefore each separated from one another by the third regions. The third regions may form or include a step or space in the “shadow” of the first regions. As a result, separate, differently-doped charge carrier-selective contacts with a fine separation of a few micrometers and a high resolution can be implemented without further complex structuring steps.

The first conductive layers can be p-type or n-type (or positive type or negative type) layers. The second conductive layers can also be p-type or n-type layers. The first conductive layers and the second conductive layers are amorphous, partially crystalline, or polycrystalline, and thus, can have a different morphology from the semiconductor substrate (or silicon base), which may be crystalline, especially monocrystalline.

In the present context, “undoped” does not mean that no additional (process-related) doping is performed. An undoped layer may be an intrinsic layer or may have the same doping (type and concentration) as the semiconductor substrate. The semiconductor substrate can have a low doping, for example in the range of 5×10¹⁶ cm⁻³. An “undoped” layer can therefore have the same or similarly low doping as the substrate. Accordingly, “doped” refers to a layer or structure to or on which additional doping is conducted, relative to the semiconductor substrate.

The third regions can have a third conductive layer. The third conductive layer can be lightly doped or have a high resistance. The surface of the semiconductor substrate in the third regions can therefore be doped, but so slightly that the electrical resistance between the first two conductive, especially doped, layers is high and does not, or only slightly, affects the efficiency of the solar cell.

According to a further embodiment of the solar cell, a fourth conductive layer may be on or in the front side of the solar cell. The fourth conductive layer may be or comprise a doped silicon layer. This can further improve the efficiency of the solar cell.

According to an even further embodiment of the solar cell, the semiconductor substrate, the first conductive layers, the second conductive layers, the third conductive layers (or third regions) and/or the fourth conductive layer may have a doping according to one of the combinations in Table 1 below:

TABLE 1

| | | | | Front side |
|---|---|---|---|---|
| | First | Second | Third conductive | or fourth |
| Semiconductor | conductive | conductive | layer or third | conductive |
| substrate | layer | layer | region | layer |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

Here, and in particular in Table 1, “p” refers to an additional positive doping compared to the semiconductor substrate, “n” refers to an additional negative doping compared to the semiconductor substrate, and “-” means no additional doping compared to the semiconductor substrate.

The passivating tunneling layers can be realized as a dielectric, e.g., SiOx, SiNx, SiON, and thus be formed as so-called TOPCon (Tunnel Oxide Passivated Contact) or POLO (Polycrystalline Silicon on Oxide) contacts. The passivating layers can also comprise or consist essentially of amorphous silicon, thereby forming a heterojunction solar cell.

### BRIEF DESCRIPTION OF THE DRAWINGS

Further features, details, and advantages of the invention appear from the wording of the claims as well as from the following description of embodiments with reference to the drawings, which show:

FIGS. 1 to 4 schematically show a method for producing a back-contact solar cell according to a first embodiment;

FIGS. 5 and 6 schematically show the method according to a second embodiment; and

FIGS. 7 to 9 are each a respective embodiment of a solar cell produced using the method.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

In the following description and in the figures, corresponding components and elements are marked with the same reference signs. For better clarity, not all reference signs are shown in every figure.

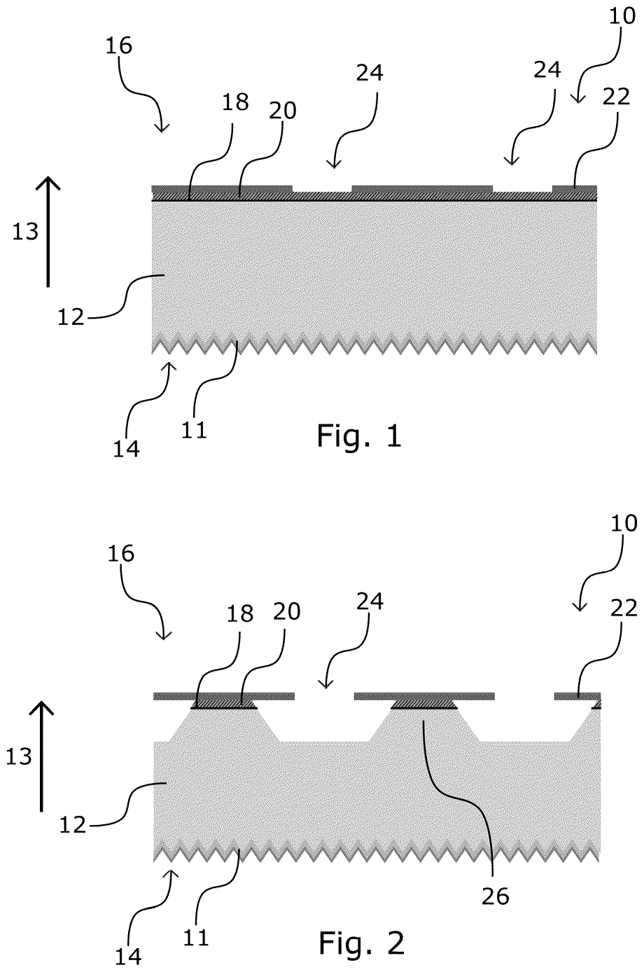

FIGS. 1 to 4 schematically show a method for producing a back-contact solar cell 10 according to a first embodiment. In each case, a schematic cross-section of the back-contact solar cell 10 is shown.

The method comprises the steps of:

Providing a semiconductor substrate 12 with a front side 14 and a back side 16.

Forming a first tunneling layer 18, in particular on the back side 16 of the semiconductor substrate 12.

Forming a first conductive layer 20 having a first doping type and optionally a first doping concentration on the first tunneling layer 18.

Forming an etch-resistant barrier layer 22 on the first conductive layer 20.

The etch-resistant barrier layer 22 can have interruptions, openings or gaps in a plurality of etch areas 24. In this case, forming (applying) the etch-resistant barrier layer 22 can, for example, comprise a printing process or deposition through a mask.

Alternatively, the etch-resistant barrier layer 22 (if formed without interruptions, openings or gaps) can be removed in the etch areas 24.

In the etch areas 24, in particular, no etch-resistant barrier layer 22 is present.

Etching in the etch areas 24, whereby pedestal-like elevations 26 are created through the etching.

Forming a second tunneling layer 28, particularly in the areas between the pedestal-like elevations 26 (i.e., in the etch areas 24 and along sidewalls of the pedestal-like elevations 26).

Forming a second conductive layer 30 with a second doping type that is opposite to the first doping type and optionally a second doping concentration, particularly in the areas between the pedestal-like elevations 26, especially in the area of the etching regions 24, and ideally not covering the sidewalls of the pedestal-like elevations 26.

Completely removing the etch-resistant barrier layer 22 and the second conductive layer 30 on the etch-resistant barrier layer 22. The above steps may carried out in the specified order.

In FIG. 1, the back side 16 of the semiconductor substrate 12 (or of the solar cell 10) is already shown with the first tunneling layer 18, the first conductive layer 20 formed on the first tunneling layer 18, and the etch-resistant barrier layer 22 formed on the first conductive layer 20. In addition, the etch-resistant barrier layer 22 has been removed in the etching areas 24 or has already been patterned, that is, applied or formed with interruptions, openings or gaps in the etching areas 24.

The process for applying the first tunneling layer 18, the first conductive layer 20, and/or the etch-resistant barrier layer 22 can be or comprise a thermal process (for example, in the case of a silicon oxide layer as the first tunneling layer 18), a CVD process (for example, for amorphous, semi-crystalline, or crystalline layers, doped or undoped, or dielectric layers), and/or a PVD process (for example, for amorphous, semi-crystalline or crystalline layers, doped or undoped layers, or dielectric layers). The etch-resistant barrier layer 22 can also be deposited over the entire surface using one of the aforementioned processes and subsequently patterned in the etching areas 24, for example by laser ablation, or it can be deposited locally through a mask or by printing. The etch-resistant barrier layer 22 can also include a polymer that has already been patterned by printing or by photolithography, laser lithography, or laser ablation.

The semiconductor substrate 12 here forms a silicon base for the solar cell. For example, the semiconductor substrate 12 may form or function as an absorber of solar radiation/light. In another embodiment, the semiconductor substrate 12 may also be or comprise a crystalline p-type silicon base.

The solar cell 10 or the semiconductor substrate 12 includes a front side 14 and a backside 16. The front side 14 faces the sun during the operation of the solar cell 10. In the illustrated embodiment, the front side 14 is textured. The front side 14 may have a fourth conductive layer 11, in particular a doped silicon layer on or at a surface thereof. The texture and doping on the front side may also be implemented at a later stage of the process.

In FIG. 2, etching is carried out in the etch areas 24. In the present case, the etching removes the first conductive layer 20, the first tunneling layer 18, and a surface of the semiconductor substrate 12 (or partially the semiconductor substrate 12). This generates pedestal-like elevations 26. In this case, the etch-resistant barrier layer 22 is undercut during the etching process. As a result, the pedestal-like elevations 26 may be formed with a cross-section that tapers in a first direction 13. In the present case, the first direction 13 is oriented away from the rear side 16 of the solar cell 10 or of the semiconductor substrate 12. In the figures, the first direction 13 points upwards.

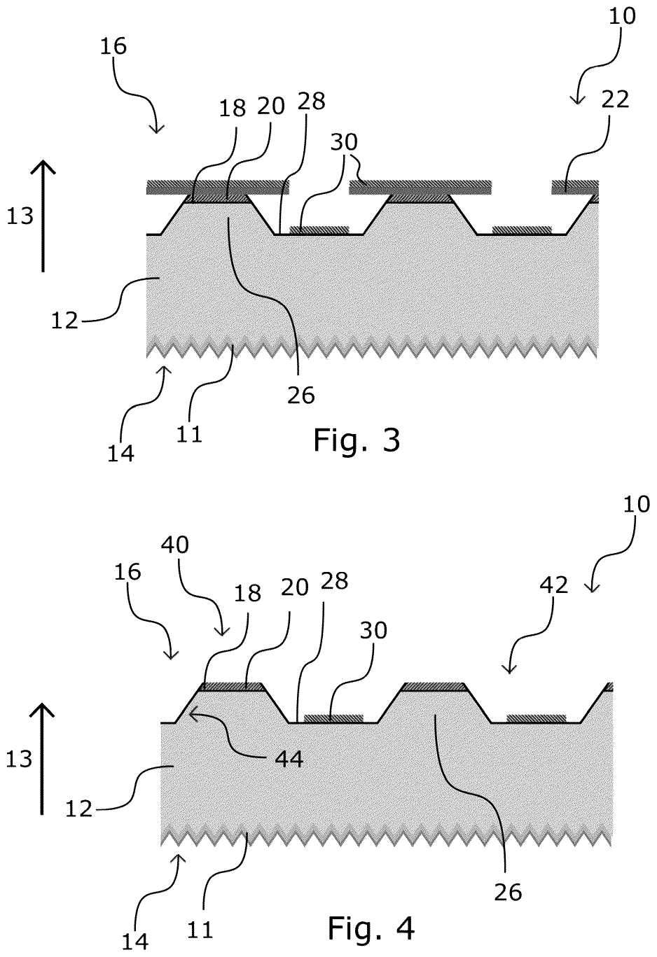

In FIG. 3, the second tunneling layer 28 and, subsequently, the second conductive layer 30 are formed. The second tunneling layer 28 can be formed by directional deposition, and hence, can cover only the unshaded areas 24. The second tunneling layer 28 can be or comprise a passivating layer, e.g., SiOx or a-Si:H.

The second tunneling layer 28 can alternatively coat the entire surface, including the third areas 44 (e.g., if deposited conformally, such as by chemical vapor deposition [CVD]; see below), or only partial areas, e.g., all silicon surfaces, for example if the passivating layer comprises a thermally grown silicon oxide layer, or only the vertically exposed or unshaded areas (thus, in this case, the first and second areas 40 and 42 [FIG. 4], not the third areas 44), if deposited by a directional process such as physical vapor deposition (PVD).

In FIG. 4, the etch-resistant barrier layer 22 and the second conductive layer 30 on the etch-resistant barrier layer 22 are completely removed. This can be carried out, for example, using a lift-off process. In this context, the second conductive layer 30 on the etch-resistant barrier layer 22 is also detached or removed. The second conductive layer 30 on the etch-resistant barrier layer 22 can be detached or removed together with the etch-resistant barrier layer 22 in a single (combined) processing step.

As a result, a plurality of first regions 40, a plurality of second regions 42, and a plurality of third regions 44 are formed on the rear side 16. The first regions 40 are represented in particular by the pedestal-like elevations 26, and particularly the uppermost surface of the pedestal-like elevations 26. A first conductive layer 20 is in each of the first regions 40. A second conductive layer 30 is in each of the second regions 42. The third regions 44 do not include either the first conductive layer 20 or the second conductive layer 30. The third regions 44 are formed in particular by under-etching the etch-resistant barrier layer 22 (i.e., etching the semiconductor substrate 12 under the etch-resistant barrier layer 22). The third regions 44 can thus be formed by the under-etched regions, at least until the etch-resistant barrier layer 22 and the second conductive layer 30 thereon are removed. In particular, the third regions 44 at least partially, and in particular fully, form a wall (e.g., a sidewall) of the pedestal-like elevations 26. The first regions 40 and/or the second regions 42 can be free of under-etching.

The second conductive layer 30 can be deposited using a directional method, e.g., PVD, and thus can cover areas that are not shadowed, but the second conductive layer 30 is not deposited in areas that are shadowed of blocked by the overhanging barrier layer 22. In the present case, the third areas 44 are therefore not covered by the second conductive layer 30.

This allows for avoiding an electrical connection between the second conductive layer 30 in the second areas 42 and the first conductive layer 20 in the first areas 40.

If small amounts of conductive material have been deposited in the third areas 44 and the conductivity of this thin layer affects the efficiency of the solar cell 10, this layer can be removed with an additional etching step.

To remove the etch-resistant barrier layer 22, a mask etchant (e.g., an etchant that selectively etches the material of the barrier layer 22) or a masking solution can be used. The mask etchant or solution is different from the etchant used to remove silicon in the etching areas 24. The mask etchant or the masking solution can be chosen such that the second conductive layer 30, particularly in the second regions 42, is not etched. Consequently, the mask etchant or solution also does not etch the first conductive layer 20 or the substrate 12, and the second conductive layer 30 is removed in the first regions 40 indirectly by the mask etchant or masking solution as or after the barrier layer 22 is etched or dissolved. The mask etchant or masking solution etches or dissolves the etch-resistant barrier layer 22, particularly laterally, until it is completely removed, leading to a lift-off or detachment of the second conductive layer 30 in the first regions 40.

The first conductive layer 20 and/or the second conductive layer 30 can be or comprise a doped silicon layer.

The first conductive layer 20 and/or the second conductive layer 30 can be doped in-situ or deposited as a conductive (e.g., heavily doped) layer. Alternatively, the first conductive layer 20 and/or the second conductive layer 30 can be deposited intrinsically, and then doped ex-situ by ion implantation and furnace diffusion, or laser diffusion.

After removing the etch-resistant barrier layer 22, the dopant(s) in the first conductive layer 20 and/or the second conductive layer 30 can be activated, and the first conductive layer 20 and/or the second conductive layer 30 can be (re) crystallized. These processes can be implemented, for example, by heating, sintering or annealing at a high-temperature. Alternatively, activation of dopant(s) in and/or crystallization of the first conductive layer 20 and/or the second conductive layer 30 can be carried out before removing the etch-resistant barrier layer 22.

After removing the etch-resistant barrier layer 22, a cleaning step, in particular to remove native oxide, can be carried out.

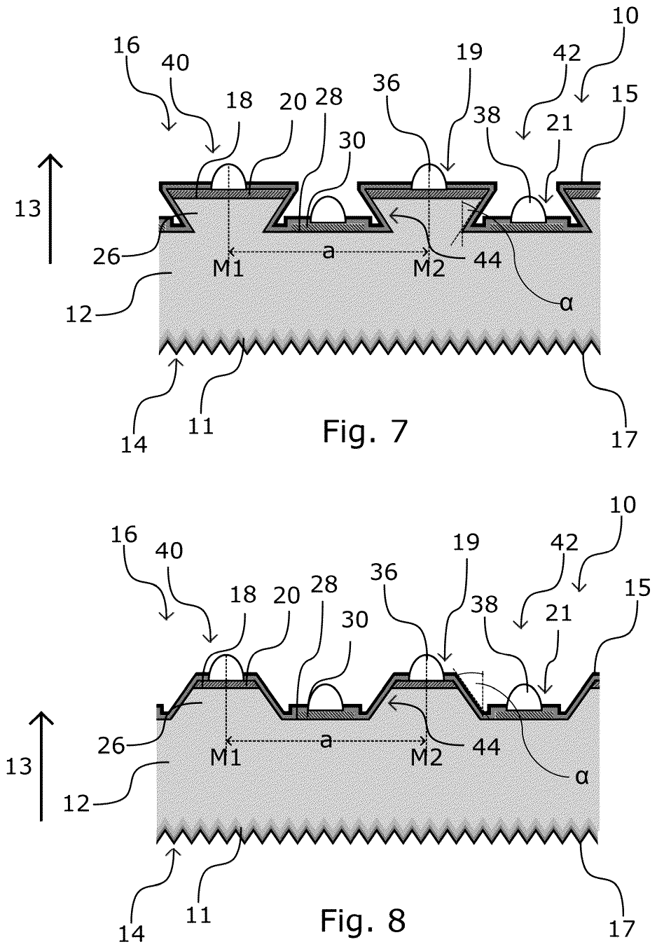

After removing the etch-resistant barrier layer 22, deposition of at least one passivation layer 15 and/or 17 (e.g., FIGS. 7-9), in particular a stack of passivation layers 15 and 17, can be carried out.

In particular, after removing the etch-resistant barrier layer 22 and deposition of the passivation layer(s) 15 and/or 17, first electrodes 36 and/or second electrodes 38 (see FIGS. 7 to 9) can be formed.

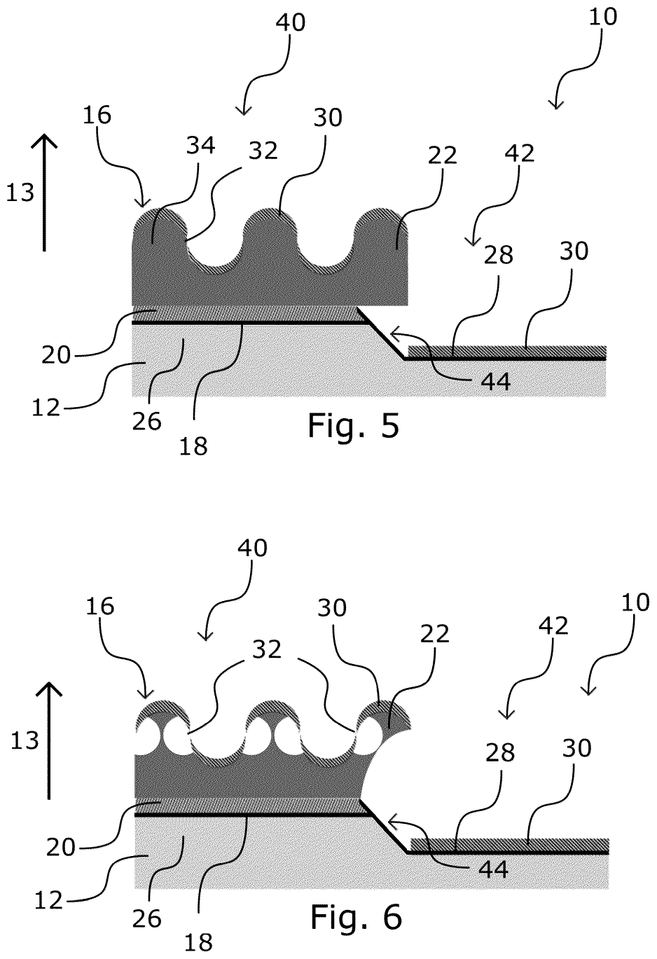

FIGS. 5 and 6 schematically show the method according to a second embodiment. Each of FIGS. 5 and 6 shows a schematic cross-section of the back-contact solar cell 10. The second embodiment differs from the first embodiment in the following way:

The removal of the etch-resistant barrier layer 22, particularly the lift-off step, can be accelerated if the second conductive layer 30 is porous and/or has holes 32, especially in the first regions 40. This allows the etching solutions or the mask solution to etch or remove the etch-resistant barrier layer 22 more quickly.

The etch-resistant barrier layer 22 may have irregularities 34 and/or be rough.

The second conductive layer 30 may only partially cover the etch-resistant barrier layer 22.

In particular, if the roughness or the irregularities 34 of the etch-resistant barrier layer 22 are greater than the layer thickness, the second conductive layer 30 may be non-continuous (i.e., have holes 32) at the irregularities 34 due to the directional PVD process (see FIGS. 5 and 6).

During the etching or dissolving of the etch-resistant barrier layer 22 using the mask etchant(s) or the mask solution, the mask etchant(s) or mask solution does not only etch or dissolve the etch-resistant barrier layer 22 from the second regions 42 toward the first regions 40, but also at the holes 32 of the second conductive layer 30 (see FIG. 6). Thus, the second conductive layer 30 can be removed more quickly.

FIGS. 7 to 9 each show an embodiment of a solar cell 10-1 manufactured using the method. A schematic cross-section through the solar cell 10-1 through 10-3 is shown in each of FIGS. 7 to 9.

FIG. 7 shows a first embodiment of the solar cell 10-1.

The solar cell 10-1 includes a semiconductor substrate 12 with a front side 14 and a back side 16. On the back side 16, a plurality of first regions 40 each with a first conductive layer 20, a plurality of second regions 42 each with a second conductive layer 30, and a plurality of third regions 44 are arranged. The third regions 44 are free of the first conductive layer 20 and the second conductive layer 30.

A first tunneling layer 18 is between the first conductive layer 20 and the semiconductor substrate 12. A second tunneling layer 28 is between the second conductive layer 30 and the semiconductor substrate 12. The first regions 40 and the second regions 42 may be or comprise passivating contacts. The solar cell 10-1 comprises a plurality of first electrodes 36 and a plurality of second electrodes 38. In the first regions 40, each first electrode 36 electrically contacts a first conductive layer 20. In the second regions 42, each second electrode 38 electrically contacts a second conductive layer 30. The first regions 40 are on pedestal-like projections 26-1.

The first conductive layers 20 and the second conductive layers 30 may, for example, each be differently doped amorphous, semi-crystalline, or polycrystalline silicon layers. For example, the first conductive layer 20 can be doped with boron and thus have p-type conductivity, and the second conductive layer 30 can be doped with phosphorus and thus have n-type conductivity. The conductive layers 20 and 30 thus differ from the (mono) crystalline silicon base (or the semiconductor substrate 12). The conductive layers 20 and 30 can also be or comprise another conductive material, e.g., doped silicon carbide SiCx.

The third regions 44 each particularly do not contain a conductive layer, or contain only a very slightly conductive layer with a very high electrical sheet resistance (e.g., Rₛₕ>1000 Ω/sq).

The first tunneling layer 18 may passivate the semiconductor substrate (or the wafer surface), particularly in the first areas 40. The second tunneling layer 28 may also passivate the semiconductor substrate (or the wafer surface), particularly in the second areas 42. Here, a surface of the back side 16 and the front side 14 of the semiconductor substrate 12 or the solar cell 10 is each at least partially, in particular fully, covered with a dielectric layer 15 and/or 17, or a stack of dielectric layers 15 and 17. The dielectric layers 15 and 17 can each comprise two or more layers. The dielectric layers 15 and 17 can passivate the back side 16 and/or front side 14, reduce reflections on the back side 16 and/or front side 14, and improve the light absorption of the solar cell 10. The dielectric layers 15 and 17 can, for example, include an aluminum oxide (AlOx, e.g. Al₂O₃), a silicon oxide (SiOx, e.g. SiO₂), and/or silicon nitride (SiNx, e.g. Si₃N₄).

The dielectric layers 15 and 17 can be formed as a layer stack (i.e., comprising or consisting of a plurality of layers). The layer stacks can each comprise or consist of two or more layers, including, for example, AlOx, SiOx and/or SiNx. Other layers for reducing reflection and/or improving passivation are also conceivable. The dielectric layer 17 or layer stack on the front side 14 and the dielectric layer 15 or layer stack on the back side 16 can be identical or different in structure and/or composition.

In the present case, the dielectric layer 15 comprises, in the area of the first regions 40, a first interruption, opening or gap 19 and, in the area of the second regions 42, a second interruption, opening or gap 21.

The solar cell 10-1 comprises a plurality of first electrodes 36 and a plurality of second electrodes 38. Each first electrode 36 contacts, in this case, a first conductive layer 20 through one or more first interruptions, openings or gaps 19. Each second electrode 38 contacts a second conductive layer 30 through one or more second interruptions, openings or gaps 21.

The first areas 40 are here on pedestal-like elevations 26-1. The elevations 26-1 each have a cross-section that widens in the first direction 13. A wall of the cross-section of the elevations 26-1 and the first direction 13 form an angle α, wherein the angle α<90° (e.g., 5°≤α≤45°). In other words, a wall of the cross-section of the pedestal-like elevations 26-1 is sloped or declined with respect to the first direction 13, with the slope or declination corresponding to the angle α.

The wall of the cross-section of the pedestal-like elevations 26-1 can also be concave or convex. The wall of the cross-section of the pedestal-like elevations 26-1 can be textured, that is, formed with a texture.

The third areas 44 can be undoped.

In the example, the front side 14 includes a fourth conductive layer 11, which can be or comprise a doped silicon layer. The doped silicon layer may include p-type doped silicon. The fourth conductive layer 11 can form a so-called “Front Floating Emitter” (FFE), for example an emitter with a p-n junction, with doping opposite to that of the silicon base or the semiconductor substrate 12. The fourth conductive layer 11 can be doped with a p-type dopant, for example boron, particularly with a dopant concentration of approximately 5×10¹⁷ cm⁻³ to 1×10²⁰ cm⁻³, preferably about 5×10¹⁸ cm⁻³ to 5×10¹⁹ cm⁻³.

In another embodiment, the fourth conductive layer 11 can be doped with an n-type doping, in particular with a comparable or identical dopant concentration as when doped with a p-type dopant. In this case, the doping on the front side is referred to as a “Front Surface Field” (FSF), that is, a doping equivalent to (e.g., of the same type as, but a greater dose or concentration than) that of the silicon substrate. Thus, the fourth conductive layer 11 may be doped with an n-type dopant, for example phosphorus, particularly with a dopant concentration of about 5×10¹⁷ cm⁻³ to 1×10²⁰ cm⁻³, preferably about 5×10¹⁸ cm⁻³ to 5×10¹⁹ cm⁻³.

The front side may also be implemented without any further doping.

In different examples, a surface of the rear side 16 may be either textured over the entire surface or chemically polished over the entire surface. The surface of the rear side 16 may also include a combination of textured areas and polished areas. For instance, the surface in the region of the first areas 40 may be planar (polished), while the surface in the region of the second areas 42 may be textured (or vice versa). The combination of textured areas and polished areas can be achieved, for example, by chemical polishing or chemical-mechanical polishing, after an anisotropic silicon etch with hot potassium hydroxide.

In the present case, the first areas 40 and the second areas 42 each alternate with one another. A distance a between the center M1 of a first area 40 and the center M2 of the next first area 40 is, for example, between 100 μm and 3000 μm, preferably between 400 μm and 2000 μm. Accordingly, a distance between the center of a second area 42 and the center of the next second area 42 is, for example, between 100 μm and 3000 μm, preferably between 400 μm and 2000 μm.

Over the surface of the rear side 16, a ratio of the total area of the first areas 40 to the total area of the second areas 42 is particularly between 1:9 and 9:1, in particular between 2:8 and 8:2, preferably between 3:7 and 7:3.

The alternating pattern of the first and second areas 40 and 42 can, in principle, extend completely or at least approximately over the entire rear side 16. However, the alternating pattern can also be locally interrupted, for example in areas where busbars are placed or intended to be placed.

The layer thickness of the first conductive layers 20 and/or the second conductive layers 30 can, for example, be 20 nm to 400 nm. The first conductive layers 20 and the second conductive layers 30 may have the same layer thickness. It is also conceivable that the first conductive layers 20 and the second conductive layers 30 may have different layer thicknesses.

The first conductive layers 20 and/or the second conductive layers 30 can be doped with an n-type dopant, e.g., phosphorus, or with a p-type dopant, e.g., boron, with a dopant concentration of, for example, 1×10¹⁹ cm⁻³ to 2×10²¹ cm⁻³, preferably from 5×10¹⁹ cm⁻³ to 1×10²¹ cm⁻³. Preferably, the first conductive layers 20 and/or the second conductive layers 30 contain dopants having different conductivity types (e.g., one is p-type, and the other is n-type).

The first and/or second tunneling layers 18 and 28 can each be or comprise a dielectric tunneling layer. The first and/or second tunneling layers 18 and 28 may, for example, comprise a layer of silicon oxide (SiOx, e.g. undoped or thermal SiO₂), silicon nitride (SiNx, e.g. Si₃N₄), silicon oxynitride (SiON, e.g. SiₓO_{y}N_{z}, where y and z are each >0, and x=y/2+3z/4), or a layer of amorphous silicon (a-Si). The first and/or second tunneling layers 18 and 28 can passivate the surface of the semiconductor substrate 12 (or the silicon base). The first and/or second tunneling layers 18 and 28 may, for example, have a thickness ranging from 0.5 nm to 20 nm. This, in particular, enables the tunneling of charge carriers.

The first and/or second tunneling layers 18 and 28 can each be or comprise an amorphous, undoped, intrinsic silicon layer. The first and second conductive layers 20, 30 can independently have a thickness ranging from 0.5 nm to 100 nm, for example. The solar cell 10-1 may be a so-called heterojunction solar cell.

The first and second tunneling layers 18 and 28 can be different, in thickness and/or in composition.

The first and/or second tunneling layers 18 and 28 can each be free or substantially free of defects. It is also conceivable that the first and/or second tunneling layers 18 and 28 may have openings (e.g., so-called pinholes) on a nanometer scale (e.g., having a diameter or width of from 0.1 to 2 nm). This enables ohmic contact between the semiconductor substrate 12 (silicon base) and the first conductive layer 20 or the second conductive layer 30.

The first conductive layers 20, particularly in the first regions 40, and the second conductive layers 30, particularly in the second regions 42, are separated from each other by the third regions 44.

In particular, the second conductive layer 30 is not in the third regions 44, or is in the third regions 44 in only trace or minimal amounts. Thus, no p-n junction (or recombination current path) exists between the first conductive layers 20 and the second conductive layers 30. The surface of the third regions 44 can be covered or passivated by a dielectric layer, particularly by the second tunneling layer 28. Additionally or alternatively, the surface of the third regions 44 can be covered with the dielectric layer 15 (or a dielectric layer stack). For this purpose, unlike the second conductive layer 30, the dielectric layer 15 (or dielectric layer stack) can be formed in an undirected manner (e.g., by chemical vapor deposition [CVD]), and can also cover the surfaces of the third regions 44.

The dielectric layer 15 essentially serves to passivate the surface of the silicon base (or the semiconductor substrate 12). On the one hand, the dielectric layer 15 may serve as a hydrogen source to improve passivation with the first and/or second tunneling layers 18 and 28. On the other hand, the dielectric layer 15 may also saturate some or all of the dangling bonds on the semiconductor substrate 12 in the third regions 44, and improve passivation via the field effect. The dielectric layer 15 can also be used to optimize the optical properties of the solar cell 10-1, especially when the solar cell 10-1 is used bifacially. The dielectric layer 15 may, for example, comprise an aluminum oxide (AlOx), a silicon oxide (SiOx) and/or silicon nitride (SiNx), as described herein. The dielectric layer 15 can consist of a layer stack comprising at least two layers, for example of an aluminum oxide (AlOx), a silicon oxide (SiOx) and/or silicon nitride (SiNx). Other layers to reduce reflection and/or improve passivation are also conceivable.

The dielectric layer 15 covers, in the example of FIG. 7, almost the entire surface of the rear side 16. The dielectric layer 17 covers, in the example of FIG. 7, almost the entire surface of the front side 14.

The first and second interruptions, openings or gaps 19 and 21 are in the dielectric layer 15 on the rear side 16, and may, for example, may be formed as openings. The first and second interruptions, openings or gaps 19 and 21 allow electrical contact between the respective first conductive layers 20 or second conductive layers 30 and the corresponding first or second electrodes 36 and 38. In other words, the first and second electrodes 36 and 38 contact the first conductive layers 20 or the second conductive layers 30 through the first and second interruptions, openings or gaps 19 and 21.

The first and/or second interruptions, openings or gaps 19 and 21 can, for example, be continuous or round, square, linear or segmented interruptions or openings. Accordingly, shaped contact surfaces for the first and second electrodes 36 and 38 can be point-shaped or circular contact surfaces, or linear or segmented contact surfaces.

In the illustrated example, the first electrodes 36 contact the first conductive layers 20, which are p-type in this example. The first electrodes 36 can therefore also be referred to as positive electrodes. In the illustrated example, the second electrodes 38 contact the second conductive layers 30, which are n-type in this example. The second electrodes 38 can therefore also be referred to as negative electrodes.

The first and second (positive and negative) electrodes 36 and 38 can comprise or consist of one or more metals, such as silver, copper, and/or aluminum. The first and second electrodes 36 and 38 can, for instance, comprise a layered stack of silver and copper, in order to minimize, for example, the silver content of the metallization. In the present case, the respective first tunneling layer 18 in the first region 40 is uninterrupted (e.g., a continuous layer). Similarly, the respective second tunneling layer 28 in the second region 42 is uninterrupted (e.g., a continuous layer). It is also conceivable that the first and/or second tunneling layers 18 and 28 are interrupted in the regions of the first and/or second interruptions, openings or gaps 19 and 21.

The electrodes 36 and 38 can also be formed from one or more pastes, in which case the first and second interruptions, openings or gaps 19 and 21 can be generated while firing (i.e., heating and/or irradiating) the paste(s), which can locally dissolve the dielectric layer 15. Firing the paste(s) can also positively affect the passivation of the non-metallized surfaces, as any hydrogen in the dielectric layer 15 may be mobilized during the firing (e.g., at a high temperature), diffuse to the surface of the semiconductor substrate 12, and saturate any open bonds there.

After firing, the conductive particles in the pastes sinter together and form the first and/or second electrodes 36 and 38. The first and/or second electrodes 36 and 38 may also comprise a stack of layers, for example, silver and copper, and be formed from a paste stack. When using aluminum, the composition of the paste(s) can be chosen so that the aluminum is not alloyed with silicon, or is only minimally alloyed with silicon. Such a composition is suitable for electrodes of both polarities.

The composition of an aluminum paste can also be chosen in such a way that during firing, the aluminum alloys with the silicon and the resulting aluminum-silicon eutectic penetrates through the second conductive layer 30 (e.g., at the second interruptions, openings or gaps 21). In this process, the aluminum can further dope the silicon substrate and surround the eutectic, so that, depending on the polarity of the substrate, an Al-doped emitter or an Al-doped back field can form. Such a doping paste is particularly suitable for positive electrodes. For negative electrodes, an n-type dopant can be added to the paste, so that the paste is suitable for forming the negative electrode, and after the formation of the eutectic, an n-type doped silicon surrounds the eutectic.

The embodiments of the solar cell 10 illustrated in FIGS. 7 to 9 differ from each other with respect to the cross-sectional shape of the pedestal-like elevations 26.

FIG. 8 shows a second embodiment of the solar cell 10-2. The second embodiment differs from the first embodiment shown in FIG. 7 in the following manner.

The cross-section of the pedestal-like elevations 26-2 tapers in the first direction 13. A wall of the cross-section and the first direction 13 form an angle α, wherein the angle α<90° (e.g., 5°≤α≤45°). In other words, a wall of the cross-section of the pedestal-like elevations 26-2 is sloped or inclined relative to the first direction 13, with the slope or inclination corresponding to the angle α.

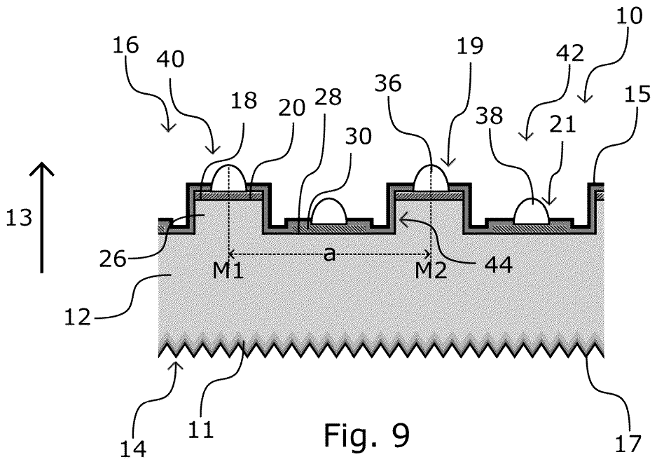

FIG. 9 shows a third embodiment of the solar cell 10-3. The third embodiment differs from the first embodiment shown in FIG. 7 in the following manner:

The cross-section of the platform-like protrusions 26-3 has a rectangular shape. The sidewalls in the cross-section of the platform-like protrusions 26-3 are parallel or substantially parallel to the first direction 13.

The individual steps of the method described above, as well as the features of the exemplary embodiments of the method and/or the solar cell, can be freely combined and/or supplemented with one another.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A method for manufacturing a back-contact solar cell, comprising:
forming a first tunneling layer on a back side of a semiconductor substrate;
forming a first conductive layer having a first doping type on the first tunneling layer;
forming an etch-resistant barrier layer on the first conductive layer, wherein the etch-resistant barrier layer has interruptions, openings or gaps in a plurality of etching areas, or is removed in the plurality of etching areas;
etching in the etching areas to produce a plurality of pedestal-like elevations and to undercut the etch-resistant barrier layer and/or the first conductive layer;
forming a second tunneling layer in the etching areas, between the plurality of pedestal-like elevations,
forming a second conductive layer having a second doping type in the etching areas, between the plurality of pedestal-like elevations, and on the etch-resistant barrier layer by directed deposition, wherein the second doping type is opposite from the first doping type, and
completely removing the etch-resistant barrier layer and the second conductive layer on the etch-resistant barrier layer.

2. The method according to claim 1, wherein completely removing the etch-resistant barrier layer and the second conductive layer comprises a lift-off process.

3. The method according to claim 1, wherein the second conductive layer is detached and/or removed when completely removing the etch-resistant barrier layer.

4. The method according to claim 3, wherein the second conductive layer is detached and/or removed together with the etch-resistant barrier layer when completely removing the etch-resistant barrier layer.

5. The method according to claim 1, wherein each of the first conductive layer and the second conductive layer comprises a doped silicon layer.

6. The method according to claim 5, wherein forming the first conductive layer and forming the second conductive layer comprise doping a silicon layer or depositing a conductive silicon layer in situ, or depositing an intrinsic silicon layer and subsequently doping the intrinsic silicon layer ex situ.

7. The method according to claim 6, wherein forming the first conductive layer and forming the second conductive layer comprise furnace diffusion, ion implantation, or laser diffusion.

8. The method according to claim 1, wherein the second conductive layer on the etch-resistant barrier layer is at least partially porous or has holes therein.

9. The method according to claim 1, wherein the etch-resistant barrier layer has irregularities or a rough surface.

10. The method according to claim 1, wherein the second conductive layer partially covers the etch-resistant barrier layer.

11. The method according to claim 1, further comprising, after removing the etch-resistant barrier layer, activating dopants in and/or crystallizing the first conductive layer and the second conductive layer.

12. The method according to claim 1, further comprising, after removing the etch-resistant barrier layer, cleaning the solar cell.

13. The method according to claim 12, wherein cleaning the solar cell removes a native oxide.

14. The method according to claim 1, further comprising, after removing the etch-resistant barrier layer, depositing at least one first passivation layer on the first conductive layer and the second conductive layer.

15. The method according to claim 14, comprising depositing a first passivation layer stack on the first conductive layer and the second conductive layer.

16. The method according to claim 14, further comprising depositing at least one second passivation layer on the front side.

17. The method according to claim 1, further comprising forming first electrodes on the first conductive layer in the first areas and forming second electrodes on the second conductive layer in the second areas.

18. The method according to claim 1, conducted in sequence.

19. A back-contact solar cell, comprising a semiconductor substrate with a front side and a rear side, a plurality of first regions each with a first conductive layer on the rear side, a plurality of second regions each with a second conductive layer on the rear side, a plurality of third regions free of both the first conductive layer and the second conductive layer on the rear side, a first tunneling layer between the first conductive layer and the semiconductor substrate, a second tunneling layer between the second conductive layer and the semiconductor substrate, a plurality of first electrodes and a plurality of second electrodes, wherein the first electrodes electrically contact the first conductive layers in the first regions, the second electrodes electrically contact the second conductive layer in the second regions, the first regions are on pedestal-like elevations of the semiconductor substrate, and the first regions and the second regions are or comprise passivating contacts.

20. The back-contact solar cell of claim 19, further comprising at least one passivation layer on at least the second conductive layer, wherein the first electrodes contact the second conductive layer through first interruptions, gaps or openings in the at least one passivation layer in the first regions, and the second electrodes contact the second conductive layer through second interruptions, gaps or openings in the passivation layer in the second regions.
